(19) United States
(12) Patent Application Publication
(10) Pub. No.: US 2016/0289827 A1
(43) Pub. Date: Oct. 6, 2016

(54) PLASMA PROCESSING SYSTEMS AND STRUCTURES HAVING SLOPED CONFINEMENT RINGS

(71) Applicant: Lam Research Corporation, Fremont, CA (US)

(72) Inventors: Edward Augustyniak, Tualatin, OR (US); Yukinori Sakiyama, I, West Linn, OR (US); Taide Tan, Tigard, OR (US); Fayaz Shaikh, Portland, OR (US)

(21) Appl. No.: 14/675,529

(22) Filed: Mar. 31, 2015

(51) Int. Cl. C23C 16/458

(52) U.S. Cl. CPC C23C 16/458

(57) ABSTRACT

A plasma chamber includes a pedestal, an upper electrode, and an annular structure. The pedestal has a central region to support a wafer and a step region that circumscribes the central region. A sloped region circumscribes the step region, with the sloped region having a top surface that slopes downward from the step region such that a vertical distance between the inner boundary of the top surface and the central region is less than a vertical distance between the outer boundary of the top surface and the central region. The upper electrode is coupled to a radio frequency power supply. An inner perimeter of the annular structure is defined to circumscribe the central region of the pedestal when the annular structure is disposed over the pedestal, and a portion of the annular structure has a thickness that increases with a radius of the annular structure.

### BACKGROUND

In semiconductor fabrication, the productivity of capacitively coupled plasma-enhanced chemical vapor deposition (PECVD) and atomic layer deposition (ALD) processes typically benefits from plasma confinement. By constraining the plasma to run above a wafer and slightly beyond the edge of the wafer, the need to fill the entire process chamber with plasma is avoided. This increases the efficiency of the process by reducing the amount of chemicals and power consumed during processing.

One known method for confining plasma in a chamber involves the use of a confinement ring that surrounds a wafer. The confinement ring, which is often made of alumina (Al₂O₃), is flat and the thickness of the confinement ring is constant. The confinement ring creates a high impedance path and decreases the local electric field. This serves to locally suppress the plasma beyond the edge of the wafer. The plasma density on the wafer increases, which results in a faster process (e.g., a higher deposition rate process).

A significant drawback of plasma confinement using a flat confinement ring is that the change of electrical impedance in the radial direction is not only abrupt but also happens very close to the edge of the wafer. The abrupt change of impedance modulates the uniformity of the plasma near the wafer edge. Consequently, non-uniform deposition at the wafer edge is a common occurrence. The flat confinement rings with uniform thickness are usually employed to provide both confinement and acceptable process uniformity as close to the wafer edge as needed. Often, however, these two goals are contradictory and the deposition occurring at the wafer edge remains non-uniform.

It is in this context that embodiments arise.

### SUMMARY

In an example embodiment, a plasma chamber includes a pedestal, an upper electrode disposed above the pedestal, and an annular structure configured to be disposed over the pedestal. The pedestal, which is configured to support a semiconductor wafer during processing, has a central region formed to support the semiconductor wafer. The central region has a top surface that is substantially flat. A step region is formed to circumscribe the central region, with the step region having a top surface formed at a location below the top surface of the central region. The pedestal has a sloped region formed to circumscribe the step region, with the sloped region having a top surface extending between an inner boundary and an outer boundary. The top surface of the sloped region is formed to slope downward from the step region such that a vertical distance between the inner boundary of the top surface of the sloped region and the central region is less than a vertical distance between the outer boundary of the top surface of the sloped region and the central region, with the vertical distances measured in a direction perpendicular to the top surface of the central region. The pedestal is electrically connected to a reference ground potential.

The upper electrode, which is disposed above the pedestal, is integrated with a showerhead for delivering deposition gases into the plasma chamber during processing. The upper electrode is coupled to a radio frequency (RF) power supply, with the RF power supply being operable to ignite a plasma between the pedestal and the upper electrode to facilitate deposition of a material layer over the semiconductor wafer during processing.

The annular structure is configured to be disposed over the pedestal. An inner perimeter of the annular structure is defined to circumscribe the central region of the pedestal when the annular structure is disposed over the pedestal, and a portion of the annular structure has a thickness that increases with a radius of the annular structure.

In one embodiment, the thickness of the portion of the annular structure increases linearly with the radius of the annular structure. In one embodiment, the thickness of the portion of the annular structure increases in accordance with a slope of the sloped region of the pedestal.

In one embodiment, the annular structure includes a step-down region having a top surface and a side surface, with the step-down region being configured so that an edge of the semiconductor wafer is disposed above the top surface of the step-down region when the semiconductor wafer is disposed over the central region of the pedestal. In one embodiment, the annular structure is configured to be movable in a vertical direction that is perpendicular to the central region of the pedestal, such that when the annular ring is lifted in the vertical direction the annular structure lifts the semiconductor wafer from the central region of the pedestal.

In one embodiment, the step region of the pedestal is provided with three or more minimum contact areas to support the annular structure, and the annular structure is not in physical contact with the sloped region of the pedestal when the annular structure is supported by the minimum contact areas.

In one embodiment, the portion of the annular structure having a thickness that increases with a radius of the annular structure provides for a gradual increase in impedance surrounding the central region of the pedestal when the plasma is ignited. In one embodiment, the sloped region of the pedestal provides for a gradual impedance increase between the central region and the periphery of the pedestal, wherein the periphery of the pedestal has a higher impedance than does the central region when the plasma is ignited. In one embodiment, the gradual impedance increase acts as a gradual confinement of the plasma over the semiconductor wafer when the plasma is ignited.

In another example embodiment, a chamber for processing a substrate includes an upper electrode disposed in the chamber, and a pedestal disposed below the upper electrode. The upper electrode is configured to be coupled to a radio frequency (RF) power supply. The pedestal, which is configured to be coupled to a reference ground potential, has a central region formed to support the substrate when present, with the central region having a top surface that is substantially flat. The pedestal has a step region formed to circumscribe the central region, with the step region having a top surface formed at a location below the top surface of the central region. Further, the pedestal has a sloped region formed to circumscribe the step region, with the sloped region having a top surface extending between an inner boundary and an outer boundary. The top surface of the sloped region is formed to slope downward from the step region such that a vertical distance between the inner boundary of the top surface of the sloped region and the central region is less than a vertical distance between the outer boundary of the top surface of the sloped region and the central region, with the vertical distances measured in a direction perpendicular to the top surface of the central region.

In one embodiment, the chamber also includes an annular structure configured to be disposed over the pedestal. An inner perimeter of the annular structure is defined to circumscribe the central region of the pedestal when the annular structure is disposed over the pedestal. Further, a portion of the annular structure has a thickness that increases with a radius of the annular structure.

In one embodiment, the portion of the annular structure having a thickness that increases with the radius of the annular structure has a wedge-shaped cross section. In one embodiment, at least a part of a lower surface of the annular structure is configured to sit on the sloped region of the pedestal, and at least part of a top surface of the annular structure is configured to be substantially parallel to the central region of the pedestal.

In one embodiment, the annular structure includes a step-down region having a top surface and a side surface, with the step-down region being configured so that an edge of the substrate is disposed above the top surface of the step-down region when the substrate is disposed over the central region of the pedestal.

In yet another example embodiment, a pedestal includes a central region, a step region, and a sloped region. The central region has a top surface that is substantially flat. The step region is formed to circumscribe the central region, with the step region having a top surface formed at a location below the top surface of the central region. The sloped region is formed to circumscribe the step region, with the sloped region having a top surface extending between an inner boundary and an outer boundary. The top surface of the sloped region is formed to slope downward from the step region such that a vertical distance between the inner boundary of the top surface of the sloped region and the central region is less than a vertical distance between the outer boundary of the top surface of the sloped region and the central region, with the vertical distances measured in a direction perpendicular to the top surface of the central region.

In one embodiment, the sloped region is oriented so that a line defined by the top surface of the sloped region defines an angle of from 1 degree to 45 degrees relative to a horizontal line defined by the top surface of the central region. In one embodiment, the angle is from 5 degrees to 30 degrees.

In still another example embodiment, an annular structure has a central portion, an inner extension portion, and an outer extension portion. The central portion has an inner boundary and an outer boundary. The central portion also has a top surface and a bottom surface, with the top surface and the bottom surface defining a thickness of the central portion. The bottom surface of the central portion is oriented at an angle relative to a line defined by the top surface of the central portion such that the thickness of the central portion increases from the inner boundary to the outer boundary.

The inner extension portion extends from the inner boundary of the central portion, with the inner extension portion having a top surface and a bottom surface. The top surface and the bottom surface define a thickness of the inner extension portion, with the thickness of the inner extension portion being less than the thickness of the central portion at the inner boundary of the central portion.

The outer extension portion extends from the outer boundary of the central portion, with the outer extension portion having a top surface and a bottom surface. The top surface and the bottom surface define a thickness of the outer extension portion, with the thickness of the outer extension portion being less than the thickness of the central portion at the outer boundary of the central portion. Further, the top surface of the outer extension portion is coplanar with the top surface of the central portion.

In one embodiment, the outer extension portion is a first outer extension portion, and the annular structure further includes a second outer extension portion that extends from the outer boundary of the central portion, with the second outer extension portion having a top surface and a bottom surface. The top surface and the bottom surface define a thickness of the second outer extension portion, with the thickness of the second outer extension portion being less than the thickness of the central portion at the outer boundary of the central portion. Further, the bottom surface of the second outer extension portion is coplanar with the bottom surface of the central portion.

In one embodiment, the annular structure further includes a third outer extension portion that extends from the outer boundary of the central portion. The third outer extension portion has a top surface and a bottom surface, with the top surface of the third outer extension portion being spaced apart from and substantially parallel to the bottom surface of the first outer extension portion. The bottom surface of the third outer extension portion is spaced apart from and substantially parallel to the top surface of the second outer extension portion.

Other aspects and advantages of the disclosures herein will become apparent from the following detailed description, taken in conjunction with the accompanying drawings, which illustrate by way of example the principles of the disclosures.

### BRIEF DESCRIPTION OF THE DRAWINGS

FIG. 1 is a schematic diagram that illustrates a substrate processing system, in accordance with an example embodiment.

FIG. 2A is a schematic diagram that illustrates a simplified cross-sectional view of plasma confinement in a plasma processing system including a carrier ring that is wedge-shaped in cross section, in accordance with an example embodiment.

FIG. 2B is graph showing impedance (Z) versus distance for the plasma processing example illustrated in FIG. 2A.

FIG. 2C is a graph that shows the normalized deposition thickness for a 450 mm wafer (with 2 mm edge exclusion) versus wafer position based on model runs using 1) a typical pedestal that accommodates a flat focus ring, and 2) an inclined pedestal that accommodates a focus ring that is wedge-shaped in cross section, in accordance with an example embodiment.

FIG. 3A illustrates a cross-sectional view of a pedestal configured to accommodate a confinement ring that is wedge-shaped in cross section, in accordance with an example embodiment.

FIG. 3B is a top view of a pedestal that illustrates the locations of the contact support structures, in accordance with an example embodiment.

FIG. 3C is an enlarged view of the transition between the step region and the sloped region of the pedestal, in accordance with an example embodiment.

FIG. 3D is an enlarged view of the transition between the step region and the sloped region of the pedestal, in accordance with another example embodiment.

FIG. 3E is an enlarged view of the transition between the step region and the sloped region of the pedestal, in accordance with yet another example embodiment.

FIG. 4A illustrates a cross-sectional view of a pedestal on which a semiconductor wafer and an annular structure are disposed, in accordance with an example embodiment.

FIG. 4B illustrates a cross-sectional view of a pedestal on which a semiconductor wafer and an annular structure are disposed, in accordance with another example embodiment.

FIG. 4C illustrates a cross-sectional view of a pedestal on which a semiconductor wafer and an annular structure are disposed, in accordance with yet another example embodiment.

FIGS. 5A to 5C illustrate additional configurations for the pedestal and annular structure that can be used to provide a gradual increase in impedance that improves process uniformity at the wafer edge.

FIG. 6 is a block diagram that shows a control module for controlling a substrate processing system.

### DETAILED DESCRIPTION

In the following description, numerous specific details are set forth in order to provide a thorough understanding of the example embodiments. However, it will be apparent to one skilled in the art that the example embodiments may be practiced without some of these specific details. In other instances, process operations and implementation details have not been described in detail, if already well known.

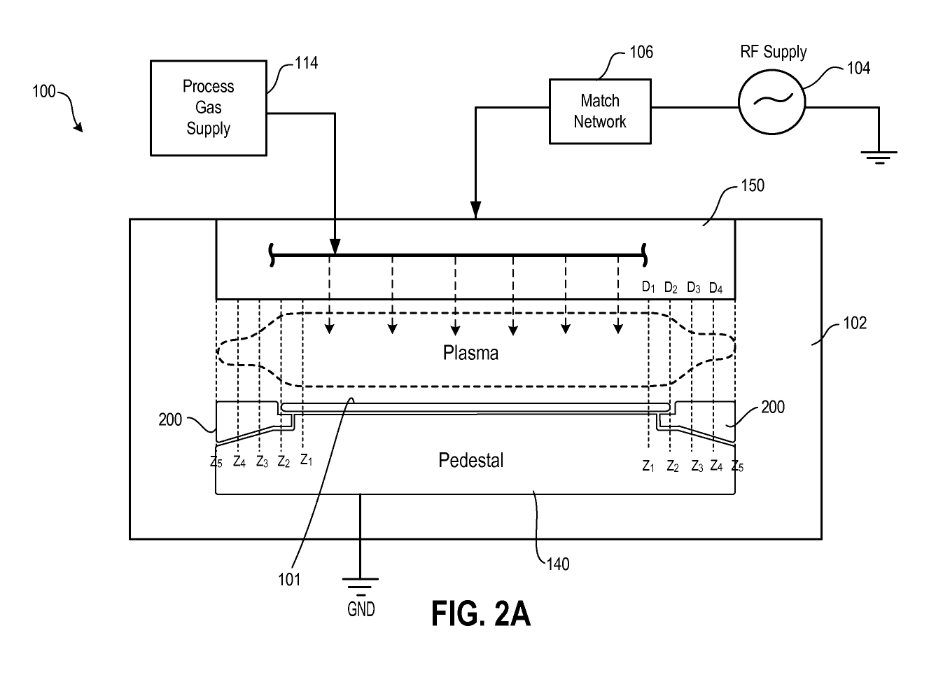

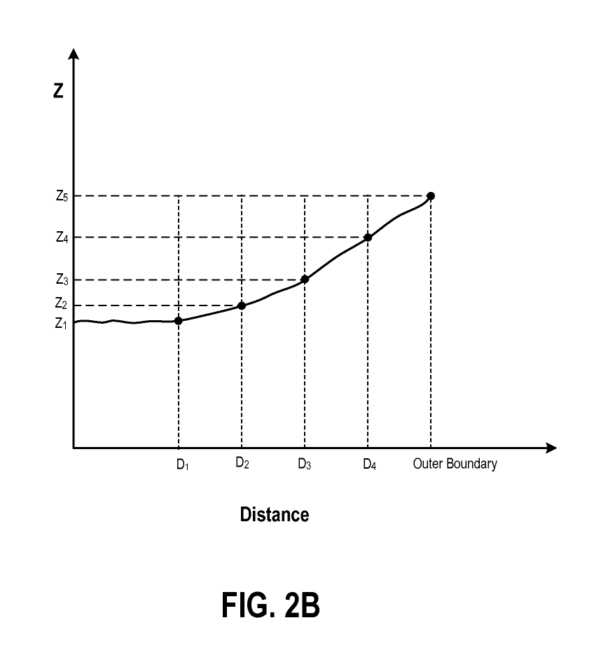

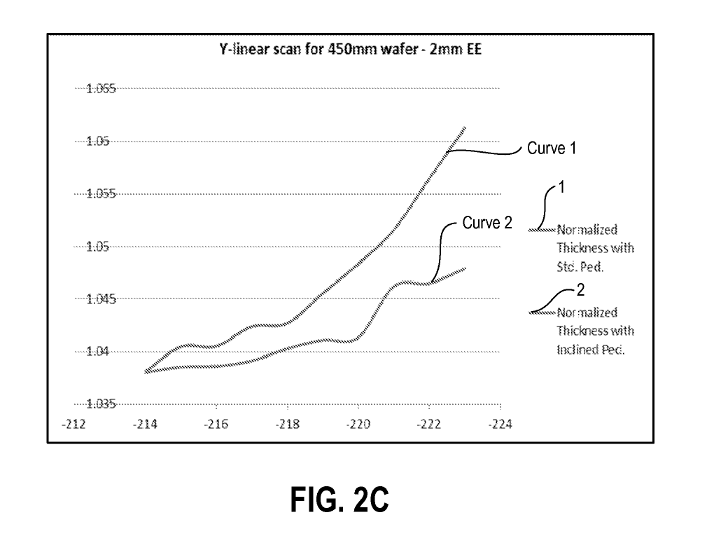

In the following embodiments, a plasma processing system having a sloped confinement ring disclosed. The sloped confinement ring is configured to surround the substrate (e.g., wafer) location and is designed to affect the impedance in a gradual manner between an inner diameter and an outer diameter of the confinement ring. The gradual increase in impedance facilitated by the sloped confinement ring assists in improving plasma confinement and eliminating abrupt changes in impedance at the edge of the wafer, which may negatively affect the uniformity of processing near the wafer edge. The embodiments of the sloped confinement ring and the sloped pedestal region shown and described herein, with particular reference to FIGS. 2A, 3A-3E, 4A-4C, and 5A-5C, contribute to the improvement in plasma confinement and enable better process uniformity to be achieved.

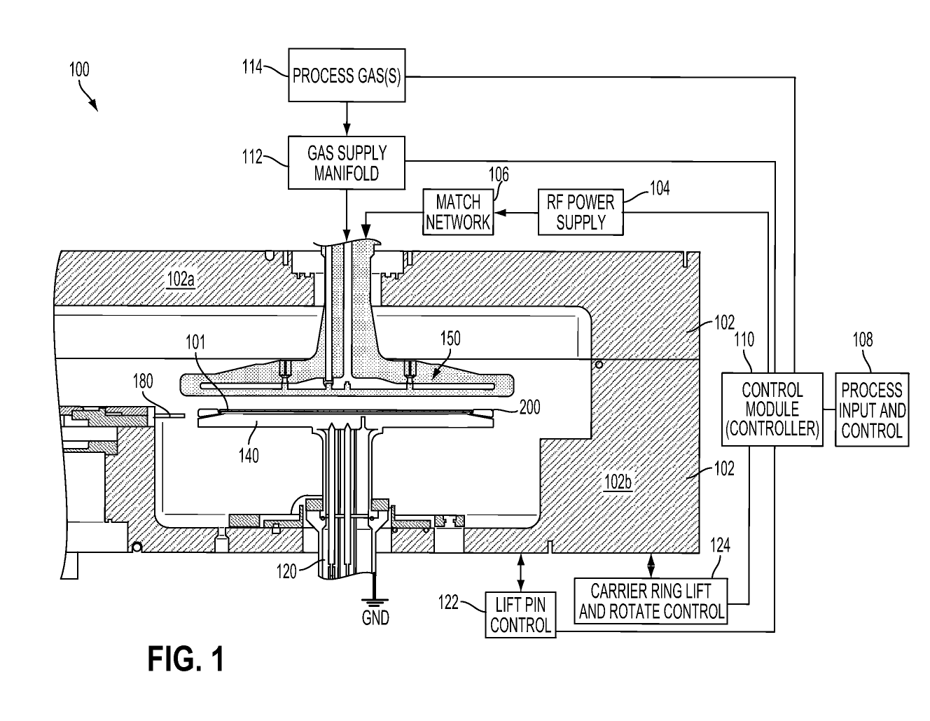

FIG. 1 is a schematic diagram that illustrates a substrate processing system 100, which is used to process a substrate 101. In one embodiment, the substrate is a silicon wafer. The system includes a chamber 102 having a lower chamber portion 102b and an upper chamber portion 102a. A center column is configured to support a pedestal 140, which in one embodiment is a grounded electrode. In the illustrated example, a shower head 150 is electrically coupled to power supply 104 via a match network 106. In other embodiments, the pedestal 140 can be powered and the shower head 150 can be grounded. The power supply is controlled by a control module 110, e.g., a controller. The control module 110 is configured to operate the substrate processing system 100 by executing process input and control 108. The process input and control 108 may include process recipes, such as power levels, timing parameters, process gasses, mechanical movement of the wafer 101, etc., such as to deposit or form films over the wafer 101.

The center column is also shown to include lift pins 120, which are controlled by lift pin control 122. The lift pins 120 are used to raise the wafer 101 from the pedestal 140 to allow an end-effector to pick the wafer and to lower the wafer after being placed by the end-effector. The substrate processing system 100 further includes a gas supply manifold 112 that is connected to process gases 114, e.g., gas chemistry supplies from a facility. Depending on the processing being performed, the control module 110 controls the delivery of process gases 114 via the gas supply manifold 112. The chosen gases are flowed into the shower head 150 and distributed in a space volume defined between the face of showerhead 150 that faces the wafer 101 and the top surface of the wafer resting over the pedestal 140.

The process gases may be premixed or not. Appropriate valving and mass flow control mechanisms may be employed to ensure that the correct gases are delivered during the deposition and plasma treatment phases of the process. Process gases exit the chamber 102 via a suitable outlet. A vacuum pump (e.g., a one or two stage mechanical dry pump and/or a turbomolecular pump) draws process gases out and maintains a suitably low pressure within the reactor by a closed loop controlled flow restriction device, such as a throttle valve or a pendulum valve.

With continuing reference to FIG. 1, a carrier ring 200 encircles an outer region of the pedestal 140. The carrier ring is configured to support the wafer during transport of the wafer to or from the pedestal. The carrier ring 200 is configured to sit over a carrier ring support region that is a step down from a wafer support region in the center of the pedestal 140. The carrier ring 200 includes an outer edge side of its annular structure, e.g., outer radius, and a wafer edge side of its annular structure, e.g., inner radius, that is closest to where the wafer 101 sits. The wafer edge side of the carrier ring 200 includes a plurality of contact support structures which are configured to lift the wafer 101 when the carrier ring is lifted by spider forks 180. The carrier ring 200 is therefore lifted along with the wafer 101 and can be rotated to another station, e.g., in a multi-station system.

As shown in FIG. 1, the carrier ring 200 has a wedge-shaped cross section, with the thinner portion of the carrier ring being toward the inner radius and the thicker portion of the carrier ring being toward the outer radius. To accommodate the slanted bottom surface of the carrier ring 200, the pedestal 140 is provided with an inclined surface that matches the slope of the slanted bottom surface of the carrier ring. The gradual change in the thickness of the carrier ring 200 results in a gradual change in impedance, which smooths the gradient of plasma and allows uniform deposition at the wafer edge, as will be explained in more detail below. Additional details regarding the configuration of confinement rings that are wedge-shaped in cross section are described in more detail below with references to FIGS. 2A, 3A-3E, 4A-4C, and 5A-5C.

FIG. 2A is a schematic diagram that illustrates a simplified cross-sectional view of plasma confinement in a plasma processing system including a carrier ring that is wedge-shaped in cross section, in accordance with an example embodiment. As shown in FIG. 2A, plasma is ignited in plasma processing system 100 in the space defined between the top surface of wafer 101 and the bottom surface of showerhead 150, which also functions as an electrode. The designations D₁, D₂, D₃, and D₄ indicate positions relative to the wafer 101 and the carrier ring 200. As shown in FIG. 2A, position D₁ is located above the surface of wafer 101 at a point situated over the central region of the pedestal 140, position D2 is located at the edge of the wafer, and positions D₃ and D₄ are located above the top surface of carrier ring 200. The impedance at each of positions D₁, D₂, D₃, and D₄ is Z₁, Z₂, Z₃, and Z₄, respectively. The designation Z5 denotes the impedance at the outer boundary, e.g., outer diameter, of carrier ring 200, which corresponds to the outer boundary of pedestal 140.

FIG. 2B is graph showing impedance (Z) versus distance for the plasma processing example illustrated in FIG. 2A. The impedance modulates as a function of the thickness of the carrier ring 200 because the carrier ring is formed of a dielectric material, e.g., alumina (Al₂O₃). Thus, in the example illustrated in FIG. 2A, Z5>Z4>Z3>Z2>Z1. The impedance Z1 is the lowest because position D1 is located above the wafer rather than the dielectric material from which the carrier ring is formed (see FIG. 2A). As the thickness of the carrier ring 200 increases in the radial direction (due to the wedge-shaped cross section of the carrier ring), the impedance gradually increases from Z₂ to Z₅ as shown in the graph of FIG. 2B. This impedance increase acts as a gradual confinement of the plasma over the wafer 101.

As shown in FIG. 2A, the dashed line outlining the shape of the plasma sheath indicates that the plasma density gradually transitions from a maximum over the wafer (see location D1) to a minimum at the outer boundary of the carrier ring and the pedestal. A significant benefit of the gradual change in impedance provided by wedge-shaped cross section of carrier ring 200 is that the impedance above the wafer (see, e.g., point D1) and the impedance above the carrier ring near the edge of wafer 101 (see the region proximate to point D₂, e.g., the region from just inside point D₂ to just outside of point D₂) are similar, e.g., roughly the same. In this regard, note that the shape of the plasma (as indicated by the dashed line) is fairly constant in the region between points D₁ and D₂. In addition, compare the relative values of Z₂ and Z₁ shown in the graph of FIG. 2B.

FIG. 2C is a graph that shows the normalized deposition thickness for a 450 mm wafer (with 2 mm edge exclusion) versus wafer position based on model runs using 1) a typical pedestal that accommodates a flat focus ring, and 2) an inclined pedestal that accommodates a focus ring that is wedge-shaped in cross section. As shown in FIG. 2C, curve 1 shows the normalized thickness with the typical pedestal and curve 2 shows the normalized thickness with the inclined pedestal. The relatively sharp increase in the slope of curve 1 between, for example, the wafer positions −220 and −222 indicates that non-uniform deposition occurs toward the edge of the wafer with the typical pedestal. The less dramatic increase in the slope of curve 2 between the same wafer positions (−220 and −222) indicates that the deposition that occurs toward the edge of the wafer with the inclined pedestal is more uniform than that with the typical pedestal.

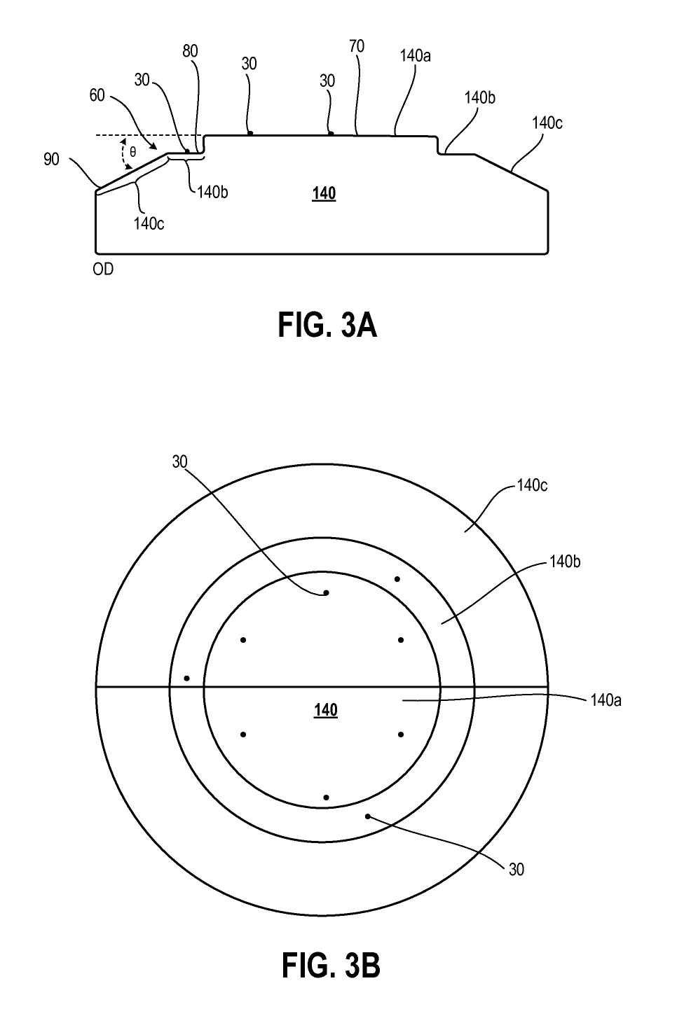

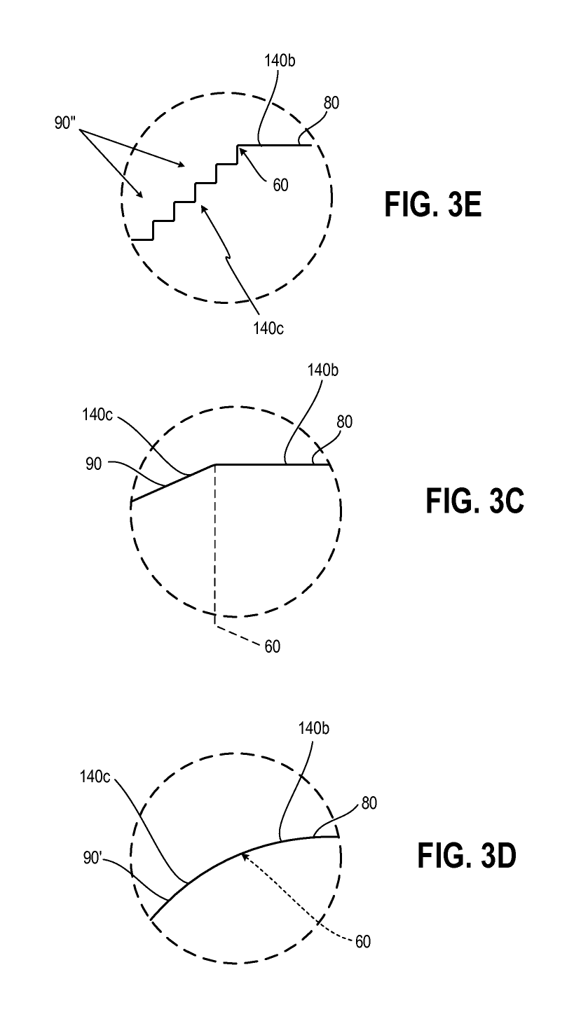

FIG. 3A illustrates a cross-sectional view of a pedestal configured to accommodate a confinement ring that is wedge-shaped in cross section, in accordance with an example embodiment. As shown in FIG. 3A, pedestal 140 includes a central region 140a, a step region 140b, and a sloped region 140c. It is noted that FIG. 3A is not drawn to scale to facilitate the illustration and description of the features of the pedestal. The top surface 70 of central region 140a is substantially flat so that the central region can support a semiconductor wafer during processing. Step region 140b circumscribes the central region 140a. In one example, the step region 140b has a width in a range from 0.25 inch to one inch. The top surface 80 of step region 140b is situated below the top surface of central region 140a. In one example, the top surface 80 of step region 140b is situated 0.25 inch below the top surface 70 of central region 140a. In another example, the top surface 80 of the step region 140b is situated below the top surface 70 of central region 140a by a distance that ranges from slightly greater than zero inch to 0.25 inch. Sloped region 140c circumscribes step region 140b. The sloped region 140c extends between an inner boundary and an outer boundary. In one embodiment, the inner boundary is the outer edge of the step region 140b and the outer boundary is the outer diameter (OD) of the pedestal 140.

The top surface 90 of the sloped region 140c slopes downward from the step region 140b. In one embodiment, the vertical distance between the inner boundary of the top surface 90 of sloped region 140c and the central region 140a is less than the vertical distance between the outer boundary (e.g., the outer diameter) of the top surface of the sloped region and the central region. In this embodiment, the vertical distances are measured in a direction perpendicular to the top surface 70 of central region 140a. As shown in FIG. 3A, the sloped region 140c is oriented so that a line defined by the top surface 90 of the sloped region defines an angle, θ, relative to a horizontal line defined by the top surface 70 of central region 140a. In one embodiment, the angle, θ, is in the range from 1 degree to 45 degrees. In other embodiments, the angle, θ, can be in the range from 5 degrees to 30 degrees or in the range from 5 degrees to 20 degrees.

The pedestal 140 can be provided with contact support structures 30, which are referred to as minimum contact areas (MCAs), to enable precision mating between surfaces. For example, contact support structures 30 can be provided in central region 140a to support the semiconductor wafer during processing. Contact support structures 30 also can be provided in step region 140b to support an annular structure that sits on the pedestal to provide plasma confinement, as will described in more detail below. FIG. 3B is a top view of pedestal 140 that illustrates the locations of the contact support structures 30, in accordance with an example embodiment. As shown in FIG. 3B, six contact support structures 30 are substantially evenly spaced around the outer portion of central region 140a. These MCAs enable precision contact to be made with the underside of the semiconductor wafer disposed above central region 140a during processing. It will be appreciated by those skilled in the art that the number of MCAs provided in the central region can be varied to suit the needs of particular applications. In the example embodiment shown in FIG. 3B, three contact support structures 30 are substantially evenly spaced around step region 140b of the pedestal 140. These MCAs enable precision contact to be made with the underside of the annular structure that sits on the pedestal, so that a portion of the annular structure can in turn make precision contact with the underside of the semiconductor wafer, e.g., in a case where the annular structure is configured to function as a carrier ring. It will be appreciated by those skilled in the art that more than three MCAs can be provided in the step region to satisfy the needs of particular applications.

FIG. 3C is an enlarged view of the transition between the step region and the sloped region of the pedestal, in accordance with an example embodiment. As shown in FIG. 3C, top surface 80 of step region 140b intersects with top surface 90 of sloped region 140 at transition 60 (transition 60 is also shown in FIG. 3A). Top surface 80 is a substantially flat surface and top surface 90 slopes downward from top surface 80 at an angle, as described above with reference to FIG. 3A.

FIG. 3D is an enlarged view of the transition between the step region and the sloped region of the pedestal, in accordance with another example embodiment. As shown in FIG. 3D, the transition 60 between top surface 80 of step region 140b and the top surface 90′ of sloped region 140c is a curved section. Away from the transition 60, top surface 80 is a non-curved surface similar to that shown in FIG. 3C. Similarly, away from the transition 60, top surface 90′ is a non-curved surface that slopes downward from top surface 80 similar to top surface 90 shown in FIG. 3C.

FIG. 3E is an enlarged view of the transition between the step region and the sloped region of the pedestal, in accordance with yet another example embodiment. As shown in FIG. 3E, top surface 80 of step region 140b intersects with top surface 90″ of sloped region 140c at transition 60. Top surface 80 is a substantially flat surface and top surface 90″ decreases from top surface 80 in a step-wise manner. In other words, top surface 90″ is a series of steps that decreases from a higher point at the top surface 80 of the step region 140b to a lower point at the outer diameter (OD) of the pedestal, where the higher and lower points are determined relative to the top surface 70 of the central region 140a of pedestal 140 (see FIG. 3A).

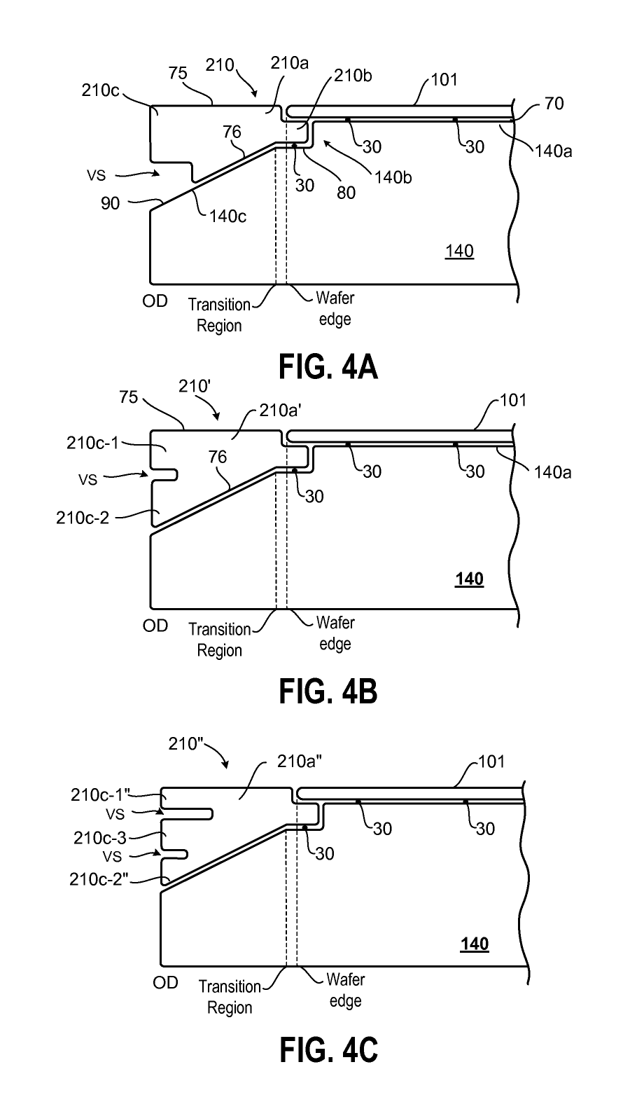

FIG. 4A illustrates a cross-sectional view of a pedestal on which a semiconductor wafer and an annular structure are disposed, in accordance with an example embodiment. As shown in FIG. 4A, semiconductor wafer 101 is supported over central region 140a of pedestal 140. The wafer 101 is supported by contact support structures 30, which, as noted above, are referred to as minimum contact areas (MCAs). The MCAs support the wafer 101 above the central region 140a of the pedestal 140 such that the underside of the wafer is spaced apart from the top surface 70 of the central region of the pedestal. The edge of wafer 101 extends beyond the edge of central region 140a of the pedestal 140 (the dashed line labeled “wafer edge” in FIG. 4A indicates the position of the wafer edge relative to the pedestal).

Annular structure 210 is disposed over pedestal 140 so that an inner perimeter of the annular structure circumscribes the central region 140a of the pedestal. The annular structure 210 includes a central portion 210a, an inner extension portion 210b, and an outer extension portion 210b. The central portion 210a has a top surface 75 and a bottom surface 76 that define the thickness of the central portion. The bottom surface 76 is oriented at an angle relative to a line defined by the top surface 75 of the central portion 210a such that the thickness of the central portion increases from the inner boundary of the central portion to the outer boundary of the central portion. Thus, the thickness of the central portion 210a of the pedestal 140 increases linearly with the radius of the annular structure. As such, the central portion 210a of the annular structure 210 has a wedge-shaped cross section. As used herein, the phrase “wedge-shaped cross section” refers to a cross section of a structure (or a portion of a structure) that has a thickness that tapers from a thicker edge or boundary to a thinner edge or boundary, where the thinner edge or boundary need not taper to a point. In one embodiment, the thickness of central portion 210a increases in accordance with the slope of sloped region 140c of pedestal 140.

The inner extension portion 210b extends from the inner boundary of the central portion 210a of the annular structure 210. The inner extension portion 210a has a thickness defined by the top and bottom surfaces of the inner extension portion. In one embodiment, the thickness of the inner extension portion 210a is less than the thickness of the central portion 210a at the inner boundary of the central portion. As shown in FIG. 4A, the configuration of the inner extension portion 210a defines a step-down region that can receive the edge of the wafer 101, which overhangs the central region 140a of the pedestal 140. The step-down region is defined by the top surface of the inner extension portion 210a and a side surface that extends from the top surface of the inner extension portion to the top surface 75 of the central portion 210a. As shown in FIG. 4A, the edge of wafer 101 is disposed over the top surface of the inner extension portion 210b and the top surface of the wafer is substantially coplanar with the top surface 75 of the central portion 210a. Further, the top surface 75 of the central portion 210a is substantially parallel to the top surface 70 of the central region 140a of the pedestal 140.

As shown in FIG. 4A, the annular structure 210 is supported by contact support structures 30 (e.g., MCAs). In particular, the bottom surface of inner extension portion 210b is supported by three (or more) MCAs provided in the step region 140b of pedestal 140. The MCAs support the annular structure 210 above the pedestal 140 such that the bottom surface 76 of the central portion 210a of the annular structure is spaced apart from the top surface 90 of the sloped region 140c of the pedestal. In addition, the bottom surface of the inner extension portion 210b is spaced apart from the top surface 80 of step region 140b of the pedestal 140. The dashed line labeled “transition region” indicates the region in which the step region 140b of the pedestal 140 transitions to the sloped region 140c of the pedestal.

The outer extension portion 210c extends from the outer boundary of the central portion 210a of the annular structure 210. The outer extension portion 210c has a thickness defined by the top and bottom surfaces of the outer extension portion. In one embodiment, the thickness of the outer extension portion 210c is less than the thickness of the central portion 210a at the outer boundary of the central portion. Further, the top surface of the outer extension portion 210c is coplanar with the top surface 75 of the central portion 210a. As shown in FIG. 4A, there is a space defined between the bottom surface of outer extension portion 210c and the top surface 90 of the sloped region 140c of the pedestal 140. This space defines a vacuum slit VS to further increase the confining action of the annular structure, as will be described in more detail below. The width of the vacuum slit VS is configured to be sufficiently narrow so as to prevent plasma from entering into the vacuum slit.

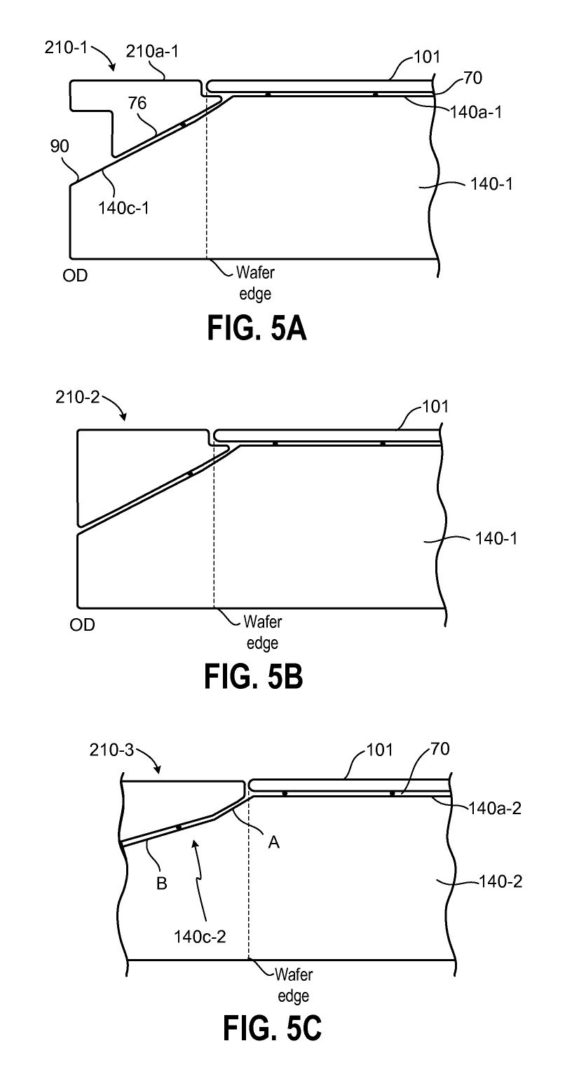

In one embodiment, the annular structure 210 is formed of alumina (Al₂O₃). It will be appreciated by those skilled in the art that the annular structure can be formed of other suitable dielectric materials. The annular structure 210 shown in FIG. 4A functions to confine plasma and thus can be referred to as a “confinement ring.” In some cases, the annular structure 210 may also function as a “carrier ring,” e.g., as shown in FIGS. 4A-4C. As a result, the lifting of the carrier ring will also lift the wafer so that, for example, the wafer can be moved to another processing station. It should be understood that the annular structure 210 may be configured so that the annular structure does not function as a carrier ring (see, e.g., the configuration of annular structure 210-3 shown in FIG. 5C). In other embodiments, the annular structure 210 may be referred to as a “focus ring.” In each case, the annular structure 210 functions to confine plasma and also provides for a gradual increase in impedance.

FIG. 4B illustrates a cross-sectional view of a pedestal on which a semiconductor wafer and an annular structure are disposed, in accordance with another example embodiment. The embodiment shown in FIG. 4B is the same as that shown in FIG. 4A with the exception that the configuration of annular structure has been modified to include two outer extension portions. As shown in FIG. 4B, the annular structure 210′ includes outer extension portions 210c-1 and 210c-2, each of which extends from the outer boundary of the central portion 210a′. Each of the outer extension portions 210c-1 and 210c-2 has a top surface and a bottom surface that defines a thickness of the respective outer extension portion. The thickness of each of the outer extension portions 210c-1 and 210c-2 is less than the thickness of the central portion 210a′ at the outer boundary of the central portion. Further, the top surface of the outer extension portion 210c-1 is coplanar with the top surface 75 of the central portion 210a′. The bottom surface of the outer extension portion 210c-2 is coplanar with the bottom surface 76 of the central portion 210a′. As such, the bottom surface of the outer extension 210c-2 is oriented at an angle relative to the top surface of the outer extension portion 210c-2.

As shown in FIG. 4B, a vacuum slit VS is defined in the outer perimeter of annular structure 210′ between the outer extension portions 210c-1 and 210c-2. More particularly, the vacuum slit VS is defined between the bottom surface of outer extension surface 210c-1 and the top surface of outer extension portion 210c-2. The width of the vacuum slit is selected to be narrow enough to prevent plasma from being sustained in the vacuum slit. In one example, the width of the vacuum slit is in a range from 0.020 inch to 0.100 inch. The presence of the vacuum slit increases the impedance because the vacuum dielectric constant is lower than that of any solid material. The increased impedance increases the confining action provided by the annular structure.

FIG. 4C illustrates a cross-sectional view of a pedestal on which a semiconductor wafer and an annular structure are disposed, in accordance with yet another example embodiment. The embodiment shown in FIG. 4C is similar to that shown in FIG. 4B with the exception that the configuration of annular structure has been modified to include three outer extension portions. As shown in FIG. 4C, the annular structure 210″ includes outer extension portions 210c-1″, 210c-2″, and 210c-3. The configurations of the outer extension portions 210c-1″ and 210c-2″ are similar to the configurations of the outer extension portions 210c-1 and 210c-2 shown in FIG. 4B. The outer extension portion 210c-3, which extends from the outer boundary of the central portion 210a″ of the annular structure 210″, has a top surface and a bottom surface. The top surface of the outer extension portion 210c-3 is spaced apart from and substantially parallel to the bottom surface of the outer extension portion 210c-1″. The bottom surface of the outer extension portion 210c-3 is spaced apart from and substantially parallel to the top surface of the outer extension portion 210c-2″. Thus, two vacuum slits VS are defined in the outer perimeter of annular structure 210″. The first vacuum slit is defined between outer extension portions 210c-1″ and 210c-3 and the second vacuum slit is defined between outer extension portions 210c-3 and 210c-2″. As shown in FIG. 4C, the first vacuum slit extends deeper into the annular structure 210″ than does the second vacuum slit. The width of each vacuum slit VS is selected to be narrow enough to prevent plasma from being sustained in the vacuum slit. The presence of the vacuum slits serves to increase the impedance because the vacuum dielectric constant is lower than that of any solid material.

FIGS. 5A to 5C illustrate additional configurations for the pedestal and annular structure that can be used to provide a gradual increase in impedance that improves process uniformity at the wafer edge. In the example shown in FIG. 5A, the pedestal has been modified to exclude the step region (see, for example, step region 140b shown in FIG. 3A). As shown in FIG. 5A, pedestal 140-1 includes central region 140a-1 and sloped region 140c-1. The annular structure has been modified to exclude the inner extension portion (see, for example, inner extension portion 210b shown in FIG. 4A). As shown in FIG. 5A, the central portion 210a-1 of annular structure 210-1 has a step-down region formed therein to accommodate the portion of wafer 101 that extends beyond the outer edge of central region 140a-1 of the pedestal 140-1. The bottom surface 76 of the central portion 210a-1 has a slope that matches the slope of the top surface 90 of sloped region 140c-1 of the pedestal 140-1.

In the example shown in FIG. 5B, the annular structure has been modified to remove the outer extension portion (see, for example, outer extension portion 210c shown in FIG. 4A). As shown in FIG. 5B, the thickness of annular structure 210-2 increases linearly from the outer edge of the step-down region that accommodates the wafer 101 to the outer diameter (OD) of the annular structure, which is coplanar with the OD of the pedestal 140-1. Thus, the annular structure 210-2 is wedge-shaped in cross section.

In the example shown in FIG. 5C, the annular structure has been modified to remove the step-down region that accommodates the portion of the wafer that extends beyond the central region of the pedestal. As shown in FIG. 5C, the sloped region 140c-2 of the pedestal 140-2 includes two regions having different slopes. These two regions are labeled “A” and “B” in FIG. 5C. The bottom surface of the annular structure 210-3 is oriented at two different angles so that the shape of the bottom surface matches the shape of the sloped region 140c-2 of the pedestal 140-2. With this configuration, when the annular structure 210-3 is seated on the pedestal 140-2, the entirety of the vertical surface that corresponds to the inner perimeter of the annular structure is perpendicular to the top surface 70 of the central region 140a-2 of the pedestal 140-2.

It is to be understood that FIGS. 4A-4C and FIGS. 5A-5C are not drawn to scale to facilitate the illustration and description of the features of the pedestal and the annular structure. The examples provided herein are therefore exemplary of various shapes, orientations, angles, positioning, and sizing of features. These examples will, of course, be considered when specific implementations are configured for working processing chambers. In addition, different working processing chambers operate under different conditions and process different recipes, which may drive modifications to the shapes, relative positions, relative orientations, dimensions, and specific sizing of features.

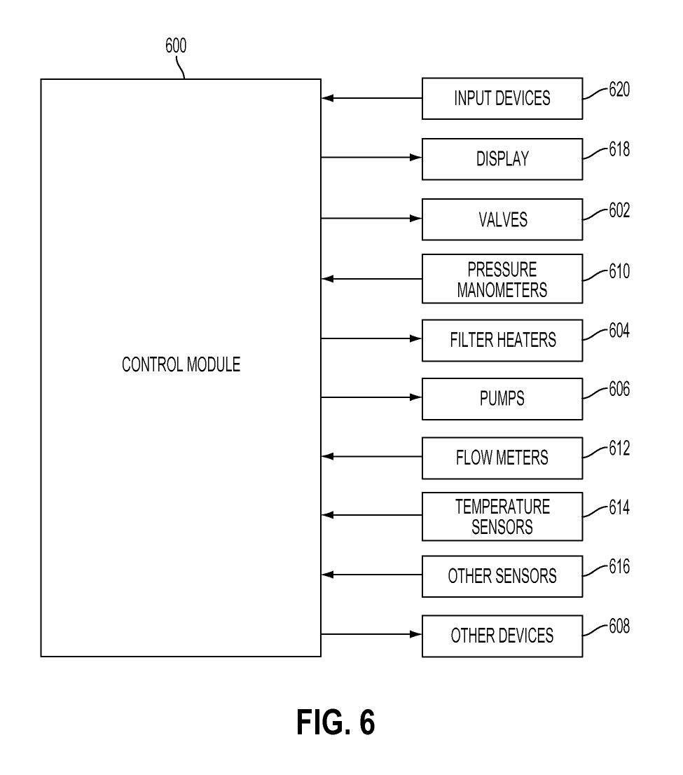

FIG. 6 is a block diagram that shows a control module 600 for controlling the systems described above. In one embodiment, the control module 110 of FIG. 1 may include some of the example components. For instance, the control module 600 may include a processor, memory and one or more interfaces. The control module 600 may be employed to control devices in the system based in part on sensed values. For example only, the control module 600 may control one or more of valves 602, filter heaters 604, pumps 606, and other devices 608 based on the sensed values and other control parameters. The control module 600 receives the sensed values from, for example only, pressure manometers 610, flow meters 612, temperature sensors 614, and/or other sensors 616. The control module 600 may also be employed to control process conditions during precursor delivery and deposition of the film. The control module 600 will typically include one or more memory devices and one or more processors.

The control module 600 may control activities of the precursor delivery system and deposition apparatus. The control module 600 executes computer programs including sets of instructions for controlling process timing, delivery system temperature, pressure differentials across the filters, valve positions, mixture of gases, chamber pressure, chamber temperature, wafer temperature, RF power levels, wafer chuck or pedestal position, and other parameters of a particular process. The control module 600 may also monitor the pressure differential and automatically switch vapor precursor delivery from one or more paths to one or more other paths. Other computer programs stored on memory devices associated with the control module 600 may be employed in some embodiments.

Typically there will be a user interface associated with the control module 600. The user interface may include a display 618 (e.g., a display screen and/or graphical software displays of the apparatus and/or process conditions), and user input devices 620 such as pointing devices, keyboards, touch screens, microphones, etc.

Computer programs for controlling delivery of precursor, deposition and other processes in a process sequence can be written in any conventional computer readable programming language: for example, assembly language, C, C++, or others. Compiled object code or script is executed by the processor to perform the tasks identified in the program.

The control module parameters relate to process conditions such as, for example, filter pressure differentials, process gas composition and flow rates, temperature, pressure, plasma conditions such as RF power levels and the low frequency RF frequency, cooling gas pressure, and chamber wall temperature.

The system software may be designed or configured in many different ways. For example, various chamber component subroutines or control objects may be written to control operation of the chamber components necessary to carry out the inventive deposition processes. Examples of programs or sections of programs for this purpose include substrate positioning code, process gas control code, pressure control code, heater control code, and plasma control code.

A substrate positioning program may include program code for controlling chamber components that are used to load the substrate onto a pedestal or chuck and to control the spacing between the substrate and other parts of the chamber such as a gas inlet and/or target. A process gas control program may include code for controlling gas composition and flow rates and optionally for flowing gas into the chamber prior to deposition in order to stabilize the pressure in the chamber. A filter monitoring program includes code comparing the measured differential(s) to predetermined value(s) and/or code for switching paths. A pressure control program may include code for controlling the pressure in the chamber by regulating, e.g., a throttle valve in the exhaust system of the chamber. A heater control program may include code for controlling the current to heating units for heating components in the precursor delivery system, the substrate and/or other portions of the system. Alternatively, the heater control program may control delivery of a heat transfer gas such as helium to the wafer chuck.

Examples of sensors that may be monitored during deposition include, but are not limited to, mass flow control modules, pressure sensors such as the pressure manometers 610, and thermocouples located in delivery system, the pedestal or chuck (e.g., the temperature sensors 614). Appropriately programmed feedback and control algorithms may be used with data from these sensors to maintain desired process conditions. The foregoing describes implementation of embodiments of the invention in a single or multi-chamber semiconductor processing tool.

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling operation thereof before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The foregoing description of the embodiments has been provided for purposes of illustration and description. It is not intended to be exhaustive or to limit the invention. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the invention, and all such modifications are intended to be included within the scope of the invention.

Accordingly, the disclosure of the example embodiments is intended to be illustrative, but not limiting, of the scope of the disclosures, which are set forth in the following claims and their equivalents. Although example embodiments of the disclosures have been described in some detail for purposes of clarity of understanding, it will be apparent that certain changes and modifications can be practiced within the scope of the following claims. In the following claims, elements and/or steps do not imply any particular order of operation, unless explicitly stated in the claims or implicitly required by the disclosure.

What is claimed is:

1. A plasma chamber, comprising:
a pedestal configured to support a semiconductor wafer during processing, the pedestal having a central region formed to support the semiconductor wafer, the central region having a top surface that is substantially flat, the pedestal having a step region formed to circumscribe the central region, the step region having a top surface formed at a location below the top surface of the central region, the pedestal having a sloped region formed to circumscribe the step region, the sloped region having a top surface extending between an inner boundary and an outer boundary, the top surface of the sloped region formed to slope downward from the step region such that a vertical distance between the inner boundary of the top surface of the sloped region and the central region is less than a vertical distance between the outer boundary of the top surface of the sloped region and the central region, with the vertical distances measured in a direction perpendicular to the top surface of the central region, the pedestal being electrically connected to a reference ground potential;
an upper electrode disposed above the pedestal, the upper electrode being integrated with a showerhead for delivering deposition gases into the plasma chamber during processing, the upper electrode being coupled to a radio frequency (RF) power supply, the RF power supply being operable to ignite a plasma between the pedestal and the upper electrode to facilitate deposition of a material layer over the semiconductor wafer during processing; and
an annular structure configured to be disposed over the pedestal, an inner perimeter of the annular structure defined to circumscribe the central region of the pedestal when the annular structure is disposed over the pedestal, and a portion of the annular structure having a thickness that increases with a radius of the annular structure.

2. The plasma chamber of claim 1, wherein the thickness of the portion of the annular structure increases linearly with the radius of the annular structure.

3. The plasma chamber of claim 1, wherein the thickness of the portion of the annular structure increases in accordance with a slope of the sloped region of the pedestal.

4. The plasma chamber of claim 1, wherein the annular structure includes a step-down region having a top surface and a side surface, the step-down region being configured so that an edge of the semiconductor wafer is disposed above the top surface of the step-down region when the semiconductor wafer is disposed over the central region of the pedestal.

5. The plasma chamber of claim 4, wherein the annular structure is configured to be movable in a vertical direction that is perpendicular to the central region of the pedestal, such that when the annular ring is lifted in the vertical direction the annular structure lifts the semiconductor wafer from the central region of the pedestal.

6. The plasma chamber of claim 1, wherein the step region of the pedestal is provided with three or more minimum contact areas to support the annular structure, and the annular structure is not in physical contact with the sloped region of the pedestal when the annular structure is supported by the minimum contact areas.

7. The plasma chamber of claim 1, wherein the portion of the annular structure having a thickness that increases with a radius of the annular structure provides for a gradual increase in impedance surrounding the central region of the pedestal when the plasma is ignited.

8. The plasma chamber of claim 1, wherein the sloped region of the pedestal provides for a gradual impedance increase between the central region and the periphery of the pedestal, wherein the periphery of the pedestal has a higher impedance than does the central region when the plasma is ignited.

9. The plasma chamber of claim 8, wherein the gradual impedance increase acts as a gradual confinement of the plasma over the semiconductor wafer when the plasma is ignited.

10. A chamber for processing a substrate, comprising:
an upper electrode disposed in the chamber, the upper electrode being configured to be coupled to a radio frequency (RF) power supply; and
a pedestal disposed below the upper electrode, the pedestal being configured to be coupled to a reference ground potential, the pedestal having a central region formed to support the substrate when present, the central region having a top surface that is substantially flat, the pedestal having a step region formed to circumscribe the central region, the step region having a top surface formed at a location below the top surface of the central region, the pedestal having a sloped region formed to circumscribe the step region, the sloped region having a top surface extending between an inner boundary and an outer boundary, the top surface of the sloped region formed to slope downward from the step region such that a vertical distance between the inner boundary of the top surface of the sloped region and the central region is less than a vertical distance between the outer boundary of the top surface of the sloped region and the central region, with the vertical distances measured in a direction perpendicular to the top surface of the central region.

11. The chamber of claim 10, further comprising,
an annular structure configured to be disposed over the pedestal, an inner perimeter of the annular structure defined to circumscribe the central region of the pedestal when the annular structure is disposed over the pedestal, and a portion of the annular structure having a thickness that increases with a radius of the annular structure.

12. The chamber of claim 11, wherein the portion of the annular structure having a thickness that increases with the radius of the annular structure has a wedge-shaped cross section.

13. The chamber of claim 11, wherein at least a part of a lower surface of the annular structure is configured to sit on the sloped region of the pedestal, and wherein at least part of a top surface of the annular structure is configured to be substantially parallel to the central region of the pedestal.

14. The chamber of claim 13, wherein the annular structure includes a step-down region having a top surface and a side surface, the step-down region being configured so that an edge of the substrate is disposed above the top surface of the step-down region when the substrate is disposed over the central region of the pedestal.

15. A pedestal, comprising:
a central region having a top surface that is substantially flat;
a step region formed to circumscribe the central region, the step region having a top surface formed at a location below the top surface of the central region; and
a sloped region formed to circumscribe the step region, the sloped region having a top surface extending between an inner boundary and an outer boundary, the top surface of the sloped region formed to slope downward from the step region such that a vertical distance between the inner boundary of the top surface of the sloped region and the central region is less than a vertical distance between the outer boundary of the top surface of the sloped region and the central region, with the vertical distances measured in a direction perpendicular to the top surface of the central region.

16. The pedestal of claim 15, wherein the sloped region is oriented so that a line defined by the top surface of the sloped region defines an angle of from 1 degree to 45 degrees relative to a horizontal line defined by the top surface of the central region.

17. The pedestal of claim 16, wherein the angle is from 5 degrees to 30 degrees.

18. An annular structure, comprising:
a central portion having an inner boundary and an outer boundary, the central portion having a top surface and a bottom surface, the top surface and the bottom surface defining a thickness of the central portion, the bottom surface of the central portion being oriented at an angle relative to a line defined by the top surface of the central portion such that the thickness of the central portion increases from the inner boundary to the outer boundary;
an inner extension portion that extends from the inner boundary of the central portion, the inner extension portion having a top surface and a bottom surface, the top surface and the bottom surface defining a thickness of the inner extension portion, the thickness of the inner extension portion being less than the thickness of the central portion at the inner boundary of the central portion; and
an outer extension portion that extends from the outer boundary of the central portion, the outer extension portion having a top surface and a bottom surface, the top surface and the bottom surface defining a thickness of the outer extension portion, the thickness of the outer extension portion being less than the thickness of the central portion at the outer boundary of the central portion, and the top surface of the outer extension portion being coplanar with the top surface of the central portion.

19. The annular structure of claim 18, wherein the outer extension portion is a first outer extension portion, and the annular structure further includes a second outer extension portion that extends from the outer boundary of the central portion, the second outer extension portion having a top surface and a bottom surface, the top surface and the bottom surface defining a thickness of the second outer extension portion, the thickness of the second outer extension portion being less than the thickness of the central portion at the outer boundary of the central portion, and the bottom surface of the second outer extension portion being coplanar with the bottom surface of the central portion.

20. The annular structure of claim 19, further comprising,
a third outer extension portion that extends from the outer boundary of the central portion, the third outer extension portion having a top surface and a bottom surface, the top surface of the third outer extension portion being spaced apart from and substantially parallel to the bottom surface of the first outer extension portion, and the bottom surface of the third outer extension portion being spaced apart from and substantially parallel to the top surface of the second outer extension portion.
